(19) United States
(12) Patent Application Publication
(10) Pub. No.: US 2025/0374479 A1
(43) Pub. Date: Dec. 4, 2025

(54) SYSTEM AND METHOD FOR COOLING VEHICLE AUTONOMY COMPUTING SYSTEM

(71) Applicant: Torc Robotics, Inc., Blacksburg, VA (US)

(72) Inventors: Dietrich Elmon Linde, Blacksburg, VA (US); Derek Barbo, Christiansburg, VA (US); Nicholas Atanasov, Austin, TX (US); Heinz Seifert, Pangburn, AR (US); Colin Butler, Salem, VA (US); Benjamin Kriebel, Blacksburg, VA (US)

(21) Appl. No.: 18/733,249

(22) Filed: Jun. 4, 2024

(51) Int. Cl. H05K 7/20; G06F 1/20

(52) U.S. Cl. CPC H05K 7/20263; G06F 1/206; H05K 7/20272; H05K 7/20281

(57) ABSTRACT

A system includes a heat exchanger coupled to a fluid line in thermal communication with an autonomy computing system of a vehicle. The heat exchanger is configured to facilitate heat transfer from fluid in the fluid line to an ambient environment. The system also includes a chiller coupled to the fluid line and configured to remove heat from the fluid when the fluid is directed to the chiller and a bypass connected to the fluid line and extending downstream of the chiller. The system further includes a controller configured to operate a valve to direct the fluid in the fluid passageway to the chiller or to the bypass.

### TECHNICAL FIELD

The field of the disclosure relates generally to cooling systems and, more specifically, cooling systems for autonomy computing systems of vehicles.

### BACKGROUND OF THE INVENTION

Autonomous vehicles, semi-autonomous vehicles, non-autonomous vehicles, and smart vehicles may include autonomy computing systems that provide information during operation of the vehicles and may at least partly operate the vehicle based on the information. For example, the sensors may include radio detection and ranging (RADAR) sensors, light detection and ranging (LiDAR) sensors, cameras, acoustic sensors, temperature sensors, or inertial navigation system (INS), and be configured to collect information regarding the environment while the vehicle is traveling. The autonomy computing system receives the information and determines operating parameters for safely operating the vehicle. Accordingly, the autonomy computing system and other parts of the vehicle generate heat that must be managed and/or removed from the systems during operation of the vehicle to ensure the system operates reliably and to increase longevity of the systems.

At least some vehicles are configured to use air-cooling to transfer heat from a heat source to the surrounding air. However, the amount of heat managed by air-cooled systems is constrained by the specific heat of the air and air cooling requires a large mass flow rate for effective heat dissipation. As a result, the air must be moved at higher flow rate to accommodate more heat generation. In addition, air-cooled systems may increase air drag due to requirements to have exposed heat exchangers; thereby reducing vehicle fuel economy efficient. In addition, the efficiency of the air-cooled systems could be improved.

Therefore, there is a need for improved autonomy computing cooling systems which enable increased heat loads; thereby enabling increases in processing power, all the while, not negatively impacting operation of the vehicle.

This section is intended to introduce the reader to various aspects of art that may be related to various aspects of the present disclosure described or claimed below. This description is believed to be helpful in providing the reader with background information to facilitate a better understanding of the various aspects of the present disclosure. Accordingly, it should be understood that these statements are to be read in this light and not as admissions of prior art.

### SUMMARY OF THE INVENTION

In one aspect, a system for cooling an autonomy computing system of a vehicle includes a fluid line in thermal communication with the autonomy computing system of the vehicle. The fluid line defines a fluid passageway for fluid to receive heat generated by the autonomy computing system. The system includes a heat exchanger coupled to the fluid line and configured to facilitate heat transfer from the fluid in the fluid passageway to an ambient environment when the fluid is directed to the heat exchanger. The system also includes a chiller coupled to the fluid line and configured to remove heat from the fluid in the fluid passageway when the fluid is directed to the chiller, a bypass connected to the fluid line and extending downstream of the chiller, and a valve coupled to the fluid line and to the bypass and configured to selectively direct the fluid in the fluid passageway to the chiller or to the bypass. The system further includes a controller communicatively coupled to the valve, the chiller, and the heat exchanger. The controller is configured to receive information relating to an operating parameter of the vehicle and, based on the received information, operate the valve to direct the fluid in the fluid passageway to the chiller or to the bypass.

In another aspect, a method for cooling an autonomy computing system of a vehicle includes directing fluid through a fluid passageway defined by a fluid line in thermal communication with the autonomy computing system of the vehicle to remove heat generated by the autonomy computing system. The method also includes directing fluid through the fluid passageway to a heat exchanger coupled to the fluid line, operating the heat exchanger to transfer heat from the fluid in the fluid passageway to the ambient environment when the fluid is directed to the heat exchanger, and receiving information relating to an operating parameter of the vehicle at a controller. The method further includes operating a valve coupled to the fluid line to selectively direct the fluid in the fluid passageway to a chiller coupled to the fluid line and configured to remove heat from the fluid in the fluid passageway when the fluid is directed to the chiller or a bypass connected to the fluid line downstream of the chiller. The controller is configured to operate the valve based on the received information to direct the fluid in the fluid passageway to the chiller or to the bypass.

In yet another aspect, a method of assembling a system for cooling an autonomy computing system of a vehicle includes positioning a fluid line defining a fluid passageway in thermal communication with the autonomy computing system such that fluid in the fluid passageway is configured to receive heat generated by the autonomy computing system. The method also includes coupling a heat exchanger to the fluid line to facilitate heat transfer from the fluid in the fluid passageway to the ambient environment when the fluid is directed to the heat exchanger, and coupling a chiller to the fluid line. The chiller is configured to remove heat from the fluid in the fluid passageway when the fluid is directed to the chiller. The method further includes connecting a bypass to the fluid line downstream of the chiller, and connecting a valve to the fluid line and to the bypass. The valve is configured to selectively direct the fluid in the fluid passageway to the chiller or to the bypass. The method includes communicatively coupling a controller to the valve, the chiller, and the heat exchanger. The controller is configured to receive information relating to an operating parameter of the vehicle and based on the received information operate the valve to direct the fluid in the fluid passageway to the chiller or to the bypass.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated examples may be incorporated into any of the above-described aspects, alone or in any combination.

### BRIEF DESCRIPTION OF DRAWINGS

The following drawings form part of the present specification and are included to further demonstrate certain aspects of the present disclosure. The disclosure may be better understood by reference to one or more of these drawings in combination with the detailed description of specific embodiments presented herein.

FIG. 1 is a schematic diagram of a vehicle;

FIG. 2 is a block diagram of a vehicle;

FIG. 3 is a schematic block diagram of a cooling system of the vehicle;

FIG. 4 is a schematic block diagram of the cooling system illustrating fluid flow through the cooling system during an optional preheat operating state;

FIG. 5 is a schematic block diagram of the cooling system illustrating fluid flow through the cooling system during cooling level 1 operating state;

FIG. 6 is a schematic block diagram of the cooling system illustrating fluid flow through the cooling system during cooling level 2 operating state;

FIG. 7 is a schematic block diagram of an embodiment of a cooling system for use with the autonomous vehicle shown in FIG. 1, the cooling system including a plurality of cooling loops;

FIGS. 8A and 8B are a flow chart of an example method of cooling a vehicle;

FIG. 9 is a block diagram of an example computing device; and

FIG. 10 is a schematic block diagram of the cooling system of FIGS. 3-6, illustrating fluid flow through the cooling system during an optional cooling level 3 operating state.

Corresponding reference characters indicate corresponding parts throughout the several views of the drawings. Although specific features of various examples may be shown in some drawings and not in others, this is for convenience only. Any feature of any drawing may be referenced or claimed in combination with any feature of any other drawing.

### DETAILED DESCRIPTION

The following detailed description and examples set forth preferred materials, components, and procedures used in accordance with the present disclosure. This description and these examples, however, are provided by way of illustration only, and nothing therein shall be deemed to be a limitation upon the overall scope of the present disclosure.

An autonomous vehicle: An autonomous vehicle is a vehicle that is able to operate itself to perform various operations such as controlling or regulating acceleration, braking, or steering wheel positioning, without any human intervention. An autonomous vehicle has an autonomy level of level-4 or level-5 recognized by National Highway Traffic Safety Administration (NHTSA).

A semi-autonomous vehicle: A semi-autonomous vehicle is a vehicle that is able to perform some of the driving related operations such as keeping the vehicle in lane or parking the vehicle without human intervention. A semi-autonomous vehicle has an autonomy level of level-1, level-2, or level-3 recognized by NHTSA.

A non-autonomous vehicle: A non-autonomous vehicle is a vehicle that is driven by a human driver. A non-autonomous vehicle is neither an autonomous vehicle nor a semi-autonomous vehicle. A non-autonomous vehicle has an autonomy level of level-0 recognized by NHTSA.

A smart vehicle: A smart vehicle is a vehicle installed with on-board computing devices, one or more sensors, one or more controllers, or one or more internet-of-things (IoT) devices which enables the vehicle to receive or transmit data to another vehicle or a server.

Embodiments of the present application include systems and methods for cooling a vehicle. For example, during operation of the vehicle, an autonomy computing system of the vehicle generates heat. The systems and methods described herein provide efficient management of the heat generated by the autonomy computing system without negatively impacting operation of the vehicle. The systems and methods provide increased capacity for managing the increased heat generated by autonomy computing systems.

For example, embodiments of the present application include a fluid line in thermal communication with an autonomy computing system and configured to remove heat generated by the autonomy computing system. The fluid line defines a fluid passageway. A heat exchanger is coupled to the fluid line and configured to facilitate heat transfer from the fluid in the fluid passageway to an ambient environment when the fluid is directed to the heat exchanger. A chiller is coupled to the fluid line and configured to regulate a temperature of the fluid in the fluid passageway when the fluid is directed to the chiller. A bypass is connected to the fluid line and extends downstream of the chiller. A valve is coupled to the fluid line and to the bypass and configured to selectively direct the fluid in the fluid passageway to the chiller or to the bypass. Also, a controller is communicatively coupled to the valve, the chiller, and the heat exchanger, and is configured to receive information relating to an operating parameter of the autonomous vehicle and, based on the received information, operate the valve to direct the fluid in the fluid passageway to the chiller or to the bypass. As a result, the cooling system provides an increased capacity for managing heat generated by the autonomy computing system and more efficiently manages increased heat loads.

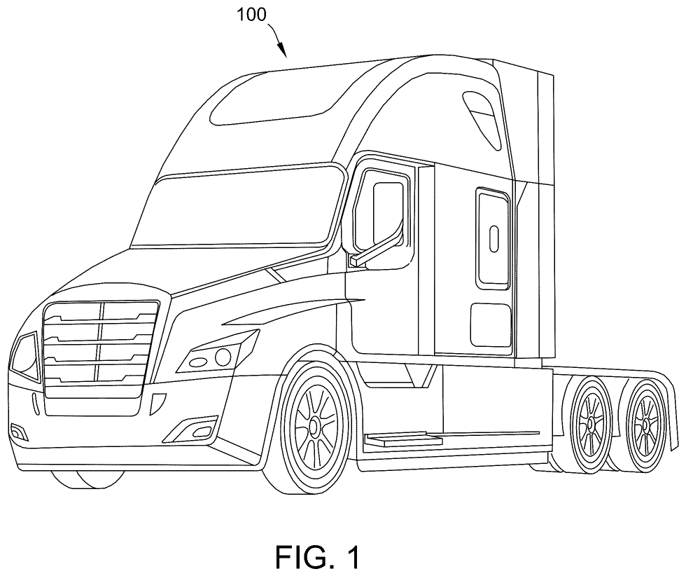

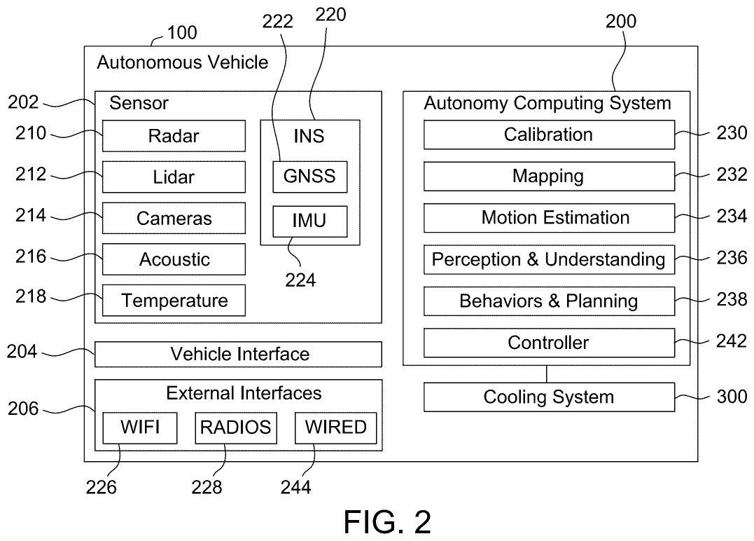

FIG. 1 is a schematic diagram of a vehicle 100. FIG. 2 is a block diagram of vehicle 100 shown in FIG. 1. In the example embodiment, vehicle 100 includes autonomy computing system 200, sensors 202, a vehicle interface 204, and external interfaces 206. For example, vehicle 100 may be an autonomous vehicle, a semi-autonomous vehicle, a non-autonomous vehicle, or a smart vehicle. In the example embodiment, vehicle 100 is an autonomous vehicle and includes autonomy computing system 200, sensors 202, a vehicle interface 204, and external interfaces 206. As described in further detail below, a cooling system 300 is configured to manage heat generated by autonomy computing system 200 and/or other components of vehicle 100.

In the example embodiment, sensors 202 may include various sensors such as, for example, radio detection and ranging (RADAR) sensors 210, light detection and ranging (LiDAR) sensors 212, cameras 214, acoustic sensors 216, temperature sensors 218, or inertial navigation system (INS) 220, which may include one or more global navigation satellite system (GNSS) receivers 222 and one or more inertial measurement units (IMU) 224. Other sensors 202 not shown in FIG. 2 may include, for example, acoustic (e.g., ultrasound), internal vehicle sensors, meteorological sensors, or other types of sensors. Sensors 202 generate respective output signals based on detected physical conditions of vehicle 100 and its proximity. As described in further detail below, these signals may be used by autonomy computing system 200 to determine how to control operation of vehicle 100.

Cameras 214 are configured to capture images of the environment surrounding vehicle 100 in any aspect or field of view (FOV). The FOV can have any angle or aspect such that images of the areas ahead of, to the side, behind, above, or below vehicle 100 may be captured. In some embodiments, the FOV may be limited to particular areas around vehicle 100 (e.g., forward of vehicle 100, to the sides of vehicle 100, etc.) or may surround 360 degrees of vehicle 100. In some embodiments, vehicle 100 includes multiple cameras 214, and the images from each of the multiple cameras 214 may be stitched or combined to generate a visual representation of the multiple cameras' FOVs, which may be used to, for example, generate a bird's eye view of the environment surrounding vehicle 100. In some embodiments, the image data generated by cameras 214 may be sent to autonomy computing system 200 or other aspects of vehicle 100, and this image data may include vehicle 100 or a generated representation of vehicle 100. In some embodiments, one or more systems or components of autonomy computing system 200 may overlay labels to the features depicted in the image data, such as on a raster layer or other semantic layer of a high-definition (HD) map.

LiDAR sensors 212 generally include a laser generator and a detector that send and receive a LiDAR signal such that LiDAR point clouds (or “LiDAR images”) of the areas ahead of, to the side, behind, above, or below vehicle 100 can be captured and represented in the LiDAR point clouds. Radar sensors 210 may include short-range RADAR (SRR), mid-range RADAR (MRR), long-range RADAR (LRR), or ground-penetrating RADAR (GPR). One or more sensors may emit radio waves, and a processor may process received reflected data (e.g., raw radar sensor data) from the emitted radio waves. In some embodiments, the system inputs from cameras 214, radar sensors 210, or LiDAR sensors 212 may be fused or used in combination to determine conditions (e.g., locations of other objects) around vehicle 100.

GNSS receiver 222 is positioned on vehicle 100 and may be configured to determine a location of vehicle 100, which it may embody as GNSS data, as described herein. GNSS receiver 222 may be configured to receive one or more signals from a global navigation satellite system (e.g., Global Positioning System (GPS) constellation) to localize vehicle 100 via geolocation. In some embodiments, GNSS receiver 222 may provide an input to or be configured to interact with, update, or otherwise utilize one or more digital maps, such as an HD map (e.g., in a raster layer or other semantic map). In some embodiments, GNSS receiver 222 may provide direct velocity measurement via inspection of the Doppler effect on the signal carrier wave. Multiple GNSS receivers 222 may also provide direct measurements of the orientation of vehicle 100. For example, with two GNSS receivers 222, two attitude angles (e.g., roll and yaw) may be measured or determined. In some embodiments, vehicle 100 is configured to receive updates from an external network (e.g., a cellular network). The updates may include one or more of position data (e.g., serving as an alternative or supplement to GNSS data), speed/direction data, orientation or attitude data, traffic data, weather data, or other types of data about vehicle 100 and its environment.

IMU 224 is a micro-electrical-mechanical (MEMS) device that measures and reports one or more features regarding the motion of vehicle 100, although other implementations are contemplated, such as mechanical, fiber-optic gyro (FOG), or FOG-on-chip (SiFOG) devices. IMU 224 may measure an acceleration, angular rate, and or an orientation of vehicle 100 or one or more of its individual components using a combination of accelerometers, gyroscopes, or magnetometers. IMU 224 may detect linear acceleration using one or more accelerometers and rotational rate using one or more gyroscopes and attitude information from one or more magnetometers. In some embodiments, IMU 224 may be communicatively coupled to one or more other systems, for example, GNSS receiver 222 and may provide input to and receive output from GNSS receiver 222 such that autonomy computing system 200 is able to determine the motive characteristics (acceleration, speed/direction, orientation/attitude, etc.) of vehicle 100.

In the example embodiment, autonomy computing system 200 employs vehicle interface 204 to send commands to the various aspects of vehicle 100 that actually control the motion of vehicle 100 (e.g., engine, throttle, steering wheel, brakes, etc.) and to receive input data from one or more sensors 202 (e.g., internal sensors). External interfaces 206 are configured to enable vehicle 100 to communicate with an external network via, for example, a wired or wireless connection, such as Wi-Fi 226 or other radios 228. In embodiments including a wireless connection, the connection may be a wireless communication signal (e.g., Wi-Fi, cellular, LTE, 5g, Bluetooth, etc.).

In some embodiments, external interfaces 206 may be configured to communicate with an external network via a wired connection 244, such as, for example, during testing of vehicle 100 or when downloading mission data after completion of a trip. The connection(s) may be used to download and install various lines of code in the form of digital files (e.g., HD maps), executable programs (e.g., navigation programs), and other computer-readable code that may be used by vehicle 100 to navigate or otherwise operate, either autonomously or semi-autonomously. The digital files, executable programs, and other computer readable code may be stored locally or remotely and may be routinely updated (e.g., automatically or manually) via external interfaces 206 or updated on demand. In some embodiments, vehicle 100 may deploy with all of the data it needs to complete a mission (e.g., perception, localization, and mission planning) and may not utilize a wireless connection or other connection while underway.

In the example embodiment, autonomy computing system 200 is implemented by one or more processors and memory devices of vehicle 100. Autonomy computing system 200 includes modules, which may be hardware components (e.g., processors or other circuits) or software components (e.g., computer applications or processes executable by autonomy computing system 200), configured to generate outputs, such as control signals, based on inputs received from, for example, sensors 202. These modules may include, for example, a calibration module 230, a mapping module 232, a motion estimation module 234, a perception and understanding module 236, a behaviors and planning module 238, a control module or controller 240. These modules may be implemented in dedicated hardware such as, for example, an application specific integrated circuit (ASIC), field programmable gate array (FPGA), or microprocessor, or implemented as executable software modules, or firmware, written to memory and executed on one or more processors onboard vehicle 100.

Autonomy computing system 200 of vehicle 100 may be completely autonomous (fully autonomous) or semi-autonomous. In one example, autonomy computing system 200 can operate under Level 5 autonomy (e.g., full driving automation), Level 4 autonomy (e.g., high driving automation), or Level 3 autonomy (e.g., conditional driving automation). As used herein the term “autonomous” includes both fully autonomous and semi-autonomous.

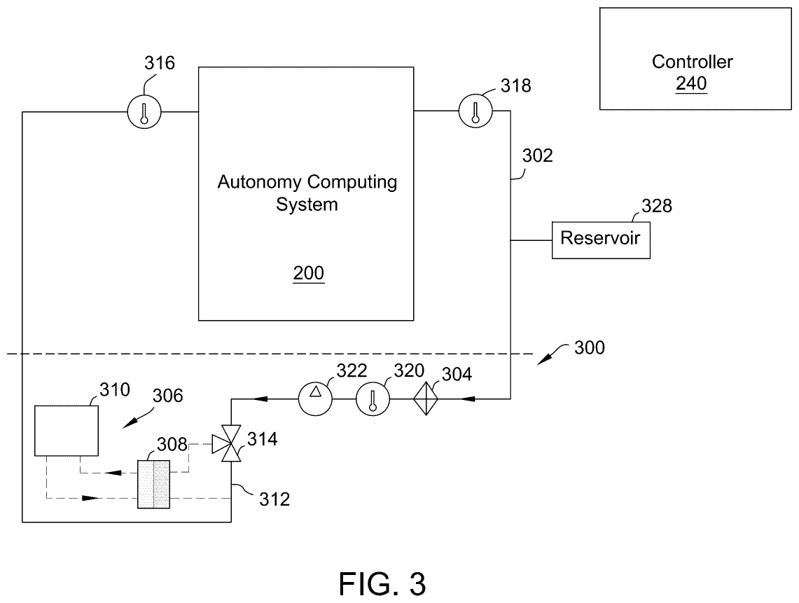

FIG. 3 is a schematic block diagram of cooling system 300 of vehicle 100. Cooling system 300 includes a fluid line 302 in thermal communication with autonomy computing system 200 and configured to remove heat generated by autonomy computing system 200. Fluid line 302 defines a fluid passageway for fluid to flow through. For example, fluid line 302 may include pipes, flexible tubing, channels, manifolds, joints, and/or any suitable components defining a fluid passageway. Fluid line 302 is arranged to receive any suitable fluid including, for example and without limitation, liquid, gas, or combinations of liquid and gas.

Fluid line 302 forms a cooling loop. For example, the fluid in fluid line 302 receives heat generated by autonomy computing system 200 and is channeled through the fluid passageway to components configured to manage the heat. In some embodiments, the fluid includes glycol or another suitable refrigerant material to facilitate the heat transfer and cooling process. The fluid in fluid line 302 is returned to autonomy computing system 200 to remove additional heat after flowing through the cooling loop.

For example, cooling system 300 includes a heat exchanger 304 coupled to fluid line 302 and configured to facilitate heat transfer from the fluid in the fluid passageway of fluid line 302 to an ambient environment when the fluid is directed to heat exchanger 304. For example, heat exchanger 304 receives the heated fluid in the fluid passageway and directs the heated fluid through a coil which interacts with forced air. The forced air removes heat from the fluid in the fluid passageway and distributes the heat to the ambient environment.

In addition, in the example, cooling system 300 includes a chiller 306 coupled to fluid line 302 and configured to regulate a temperature of the fluid in the fluid passageway when the fluid is directed to chiller 306. For example, the chiller 306 includes a heat exchanger (e.g., a liquid-to-liquid heat exchanger) 308 and a compressor 310. Heat exchanger 308 interacts with the fluid in the fluid passageway and exchanges heat between liquids. Compressor 310 is configured to facilitate the liquid cooling. Compressor 310 may be dedicated only to cooling system 300 and not connected to external components. In some embodiments, chiller 306 is coupled to a power source (e.g., an alternator) on vehicle 100 (shown in FIG. 1) and receives power only from the power source. Alternatively, compressor 310 may be dual purpose and be connected to other components of vehicle 100 such as an air conditioning system.

Also, cooling system 300 includes a bypass 312 connected to fluid line 302 upstream of chiller 306 and extending downstream of chiller 306. Bypass 312 is arranged for the fluid in the fluid passageway to flow past chiller 306 without interacting with chiller 306. For example, valve 314 is coupled to fluid line 302 and coupled to bypass 312 upstream of chiller 306. In the example, valve 314 is a three-way valve configured to selectively direct the fluid in the fluid passageway to chiller 306 or to bypass 312.

Cooling system 300 includes one or more components along fluid line 302 to facilitate fluid flow and/or provide information relating to the flow of fluid through fluid line 302. For example, cooling system 300 includes a first temperature sensor 316 positioned at an inlet or upstream of autonomy computing system 200, a second temperature sensor 318 positioned at an outlet or downstream of autonomy computing system 200, and/or a third temperature sensor 320 downstream of heat exchanger 304. Temperature sensors 316, 318, 320 are arranged to measure a temperature of the fluid in fluid line 302.

In addition, cooling system 300 includes at least one pump 322 coupled to fluid line 302 and configured to cause the fluid to flow through the fluid passageway defined by fluid line 302. For example, pump 322 may be configured to direct the fluid towards heat exchanger 304, valve 314, and/or chiller 306.

Controller 240 is communicatively coupled to valve 314, chiller 306, and/or heat exchanger 304. Controller 240 is configured to receive information relating to an operating parameter of vehicle and based on the received information actuate valve 314 to direct the fluid in the fluid passageway to chiller 306 or to bypass 312. In addition, controller 240 is configured to operate chiller 306 and/or heat exchanger 304 to manage heat carried by the fluid in fluid line 302. For example, in some embodiments, the operating parameter includes a temperature of the ambient environment around vehicle 100 or a temperature of the fluid in the fluid passageway. For example, controller 240 may be configured to receive a temperature of the ambient environment around vehicle 100 from temperature sensor 218 shown in FIG. 2.

In the example embodiment, controller 240 is configured to compare the temperature to a first threshold value and a second threshold value and controller 240 operates the cooling system 300 based on the comparison. For example, controller 240 is configured to operate the heat exchanger to remove heat from the fluid in the fluid passageway when the temperature is at or above the first threshold value. If the temperature is below the second threshold value, controller 240 operates valve 314 to direct the fluid into bypass 312 and beyond chiller 306 without the fluid interacting with chiller 306. If the temperature is at or above the second threshold value, controller 240 is configured to actuate valve 314 to direct the fluid to chiller 306. In the example, valve 314 and chiller 306 are coupled to fluid line 302 downstream of heat exchanger 304 such that fluid flows from heat exchanger 304 toward chiller 306 when valve 314 is positioned to direct the fluid toward chiller 306.

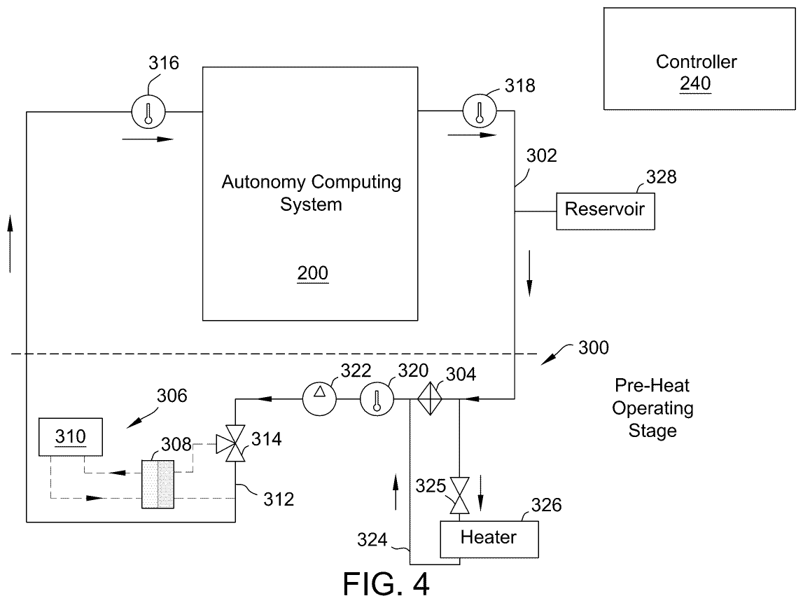

FIG. 4 is a schematic block diagram of cooling system 300 illustrating fluid flow through cooling system 300 during an optional preheat operating state. The preheat operating state may be utilized, for example, when the temperature of the ambient environment around vehicle 100 and/or the temperature of the fluid in fluid line 302 is below a first threshold value. During the preheat operating state, the fluid in fluid line 302 is heated to facilitate the fluid interacting with components of cooling system 300. Cooling system 300 may switch to a different operating state when the fluid has reached a desired temperature.

In the example embodiment, a reservoir 328 stores excess fluid and facilitates fluid movement through fluid line 302. A sensor such as a liquid level sensor may be located at reservoir 328 and arranged to detect information relating to the level of fluid within reservoir 328. The sensor may provide a signal or alert if the level of fluid within reservoir 328 is at or below a threshold level.

In the example embodiment, a preheat line 324 is coupled to fluid line 302. Preheat line 324 may include a valve 325 to regulate fluid flow through the preheat line 324. For example, valve 325 may be closed to stop fluid flow through preheat line 324 in operating states other than the preheat operating state.

Also, a heater 326 is coupled to preheat line 324 downstream of reservoir 328 and is arranged to heat the fluid directed through preheat line 324. For example, heater 326 may be an electric heater or any suitable heat source. In some embodiments, heater 326 captures and uses heat generated by components of vehicle 100 and/or cooling system 300 to provide heat to the fluid. In some embodiments, preheat line 324, heater 326, and/or reservoir 328 are omitted.

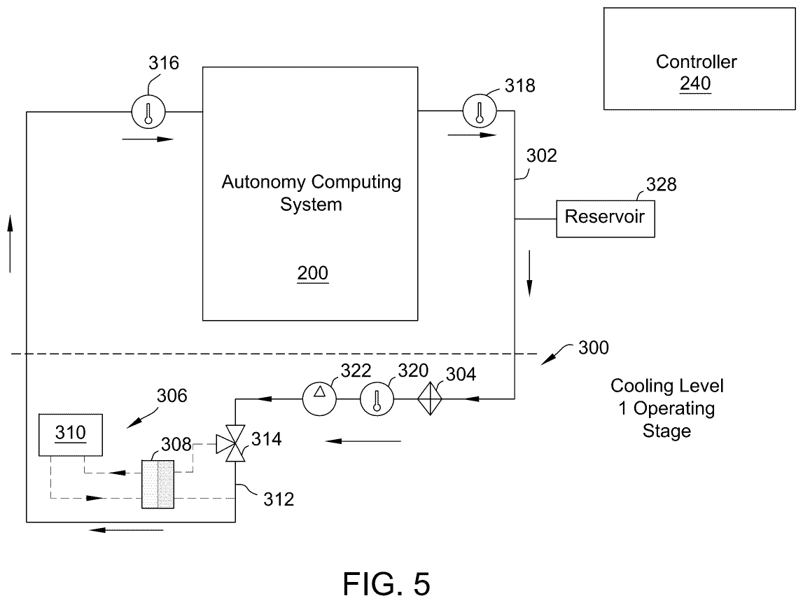

FIG. 5 is a schematic block diagram of cooling system 300 illustrating fluid flow through cooling system 300 during cooling level 1 operating state. Cooling level 1 operating state occurs when the temperature of the ambient environment around vehicle 100 and/or the temperature of the fluid in fluid line 302 is at or above the first threshold value and below a second threshold value.

When cooling system 300 operates in cooling level 1 operating state, fluid in fluid line 302 interacts with autonomy computing system 200 and receives heat generated by autonomy computing system 200. The heated fluid is directed to heat exchanger 304 and controller 240 operates heat exchanger 304 to remove heat from the fluid. After interacting with heat exchanger 304, the fluid is directed toward valve 314. Controller 240 operates valve 314 to direct the fluid into bypass 312 and beyond chiller 306 without the fluid interacting with chiller 306. Chiller 306 is in an Off state during cooling level 1 operating state. After flowing through bypass 312, the fluid flows through fluid line 302 back to autonomy computing system 200.

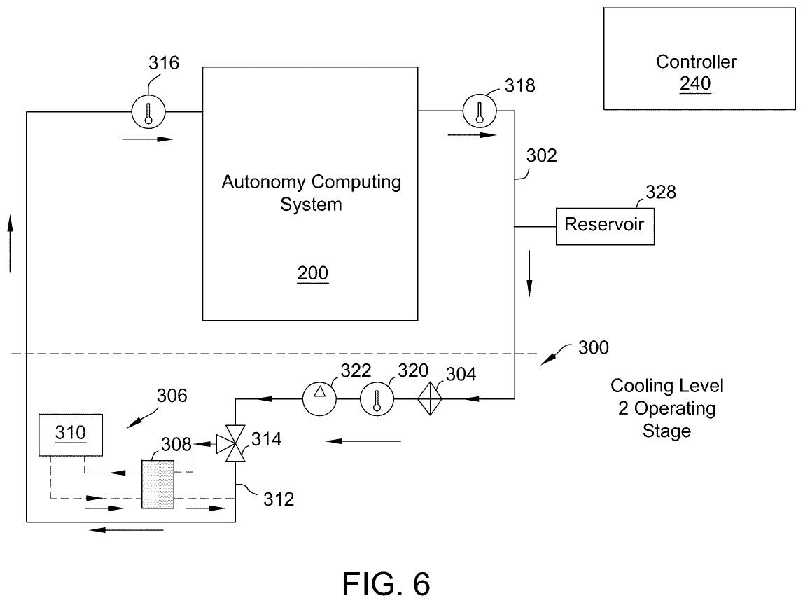

FIG. 6 is a schematic block diagram of cooling system 300 illustrating fluid flow through cooling system 300 during cooling level 2 operating state. Cooling level 2 operating state occurs when the temperature of the ambient environment around vehicle 100 and/or the temperature of the fluid in fluid line 302 is at or above the second threshold value.

When cooling system 300 operates in cooling level 2 operating state, fluid in fluid line 302 interacts with autonomy computing system 200 and receives heat generated by autonomy computing system 200. The heated fluid is directed to heat exchanger 304 and controller 240 operates heat exchanger 304 to remove heat from the fluid. After interacting with heat exchanger 304, the fluid is directed toward valve 314. Controller 240 operates valve 314 to direct the fluid toward chiller 306. Controller 240 is configured to operate chiller 306 to remove heat from the fluid in the fluid passageway when the fluid is directed to chiller 306. After interacting with chiller 306, the fluid flows through fluid line 302 back to autonomy computing system 200.

As a result, cooling system 300 provides multi-stage cooling for autonomy computing system 200 of vehicle 100. In addition, cooling system 300 provides increased efficiency and increased capacity to handle heat generated by autonomy computing system 200. Also, cooling system 300 provides less noise and vibrations than systems relying solely on air-cooling.

Referring to FIGS. 4-6, to assemble cooling system 300, fluid line 302 is positioned in thermal communication with autonomy computing system 200 such that fluid in the fluid passageway is configured to remove heat generated by autonomy computing system 200. Heat exchanger 308 is coupled to fluid line 302 to facilitate heat transfer from fluid in the fluid passageway to the ambient environment when the fluid is directed to heat exchanger 308 and heat exchanger 308 is in an ON state. Also, chiller 306 is coupled to fluid line 302 and configured to regulate a temperature of the fluid in the fluid passageway when the fluid is directed to chiller 306 and chiller 306 is in an ON state. In some embodiments, heat exchanger 308 and compressor 310 are packaged in a single unit. In other embodiments, heat exchanger 308 and compressor 310 are separate structures. For example, in some embodiments, chiller 306 utilizes a compressor of vehicle 100 as compressor 310 and does not include a standalone compressor 310.

In addition, bypass 312 is connected to fluid line 302 downstream of chiller 306. Valve 314 is connected to fluid line 302 and to bypass 312. Valve 314 is arranged to selectively direct the fluid in the fluid passageway to chiller 306 or to bypass 312.

Controller 240 is communicatively coupled to valve 314, chiller 306, and heat exchanger 308. Controller 240 is configured to receive information relating to an operating parameter of vehicle 100 and, based on the received information, actuate valve 314 to direct the fluid in the fluid passageway to chiller 306 or to bypass 312.

In the example, pump 322 is coupled to fluid line 302 to direct the fluid toward heat exchanger 308 or chiller 306. Pump 322 may be any suitable pump and is arranged to cause fluid to flow within fluid line 302 and/or bypass 312.

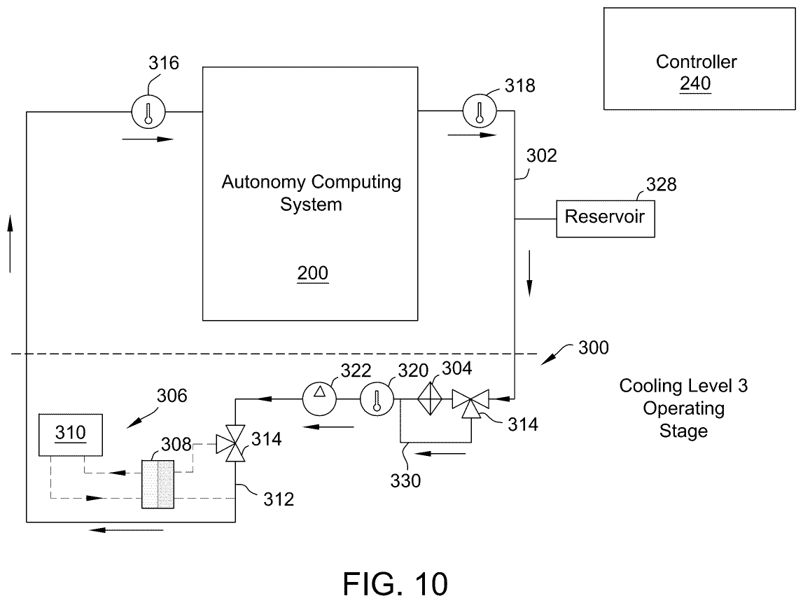

FIG. 10 is a schematic block diagram of cooling system 300 illustrating fluid flow through cooling system 300 during an optional cooling level 3 operating state. Cooling level 3 operating state occurs when the temperature of the ambient environment around vehicle 100 is at or above a third threshold value (e.g., a desired cooling state temperature). In the cooling level 3 operating state, fluid is diverted around heat exchanger 304 without interacting with heat exchanger 304. For example, in the example embodiment illustrated in FIG. 10, a heat exchanger bypass line 330 is coupled to fluid line 302 and configured for the fluid in the fluid passageway to flow past heat exchanger 304 without interacting with heat exchanger 304. Heat exchanger bypass line 330 may include valve 314 to regulate fluid flow through the heat exchanger bypass line 324. For example, valve 314 may be set to stop fluid flow through heat exchanger bypass line 330 in operating states other than the cooling level 3 operating state and allow fluid flow through heat exchanger bypass line 330 in the cooling level 3 operating state.

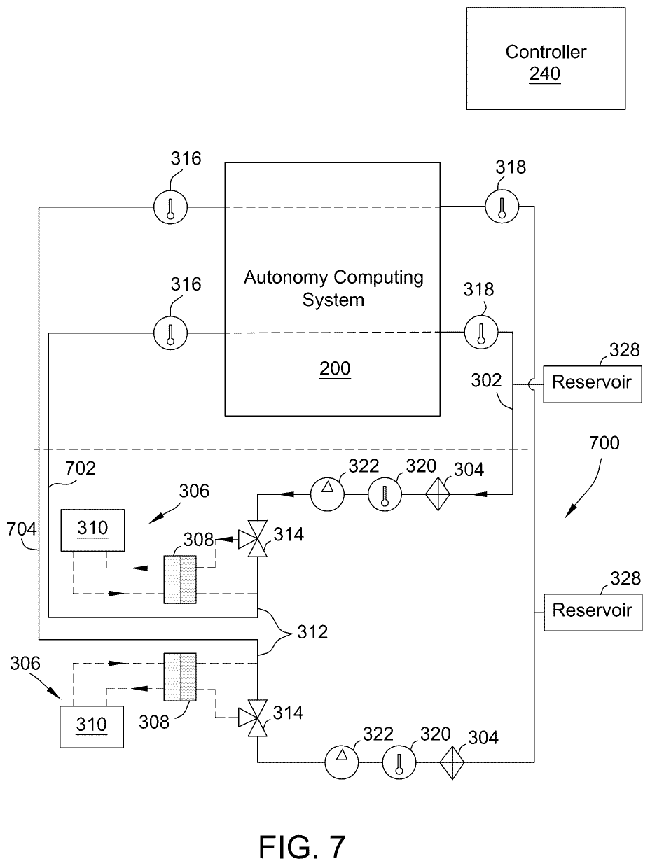

FIG. 7 is a schematic block diagram of an embodiment of a cooling system 700 for use with vehicle 100 shown in FIG. 1. Cooling system 700 is similar to cooling system 300 shown in FIGS. 3-6 and 10 except as described herein. Cooling system 700 includes a first cooling loop 702 and a second cooling loop 704. First cooling loop 702 and second cooling loop 704 provide redundant cooling loops and/or are coupled to separate portions or components of vehicle 100. In the example, first cooling loop 702 and second cooling loop 704 are coupled to autonomy computing system 200.

First cooling loop 702 and second cooling loop 704 each include fluid line 302, heat exchanger 304, chiller 306, heat exchanger 308, bypass 312, valve 314, temperature sensors 316, 318, 320 and pump 322. First cooling loop 702 and second cooling loop 704 are controlled by controller 240. First cooling loop 702 and second cooling loop 704 are arranged to operate in multiple stages as described herein and may be operated in synchronization or independently of each other.

In the example embodiment, chiller 306 of first cooling loop 702 and chiller 306 of second cooling loop 704 each include a separate compressor 310. In alternative embodiments, first cooling loop 702 and second cooling loop 704 share compressor 310. For example, compressor 310 may be dual purpose and be connected to other components of vehicle 100 and to heat exchanger 308 of first cooling loop 702 and/or heat exchanger 308 of second cooling loop 704.

First cooling loop 702 and second cooling loop 704 provide an increased capacity for managing heat generated by autonomy computing system 200. In addition, first cooling loop 702 and second cooling loop 704 may provide redundant cooling where one cooling loop provides cooling for autonomy computing system 200 if the other cooling loop is inoperable. As a result, cooling system 700 provides redundant cooling and increases the reliability of vehicle 100. For example, first cooling loop 702 or second cooling loop 704 may provide cooling to necessary components of autonomy computing system 200 and facilitate vehicle continuing traveling and/or making a safety maneuver if a portion of cooling system 700 is inoperable.

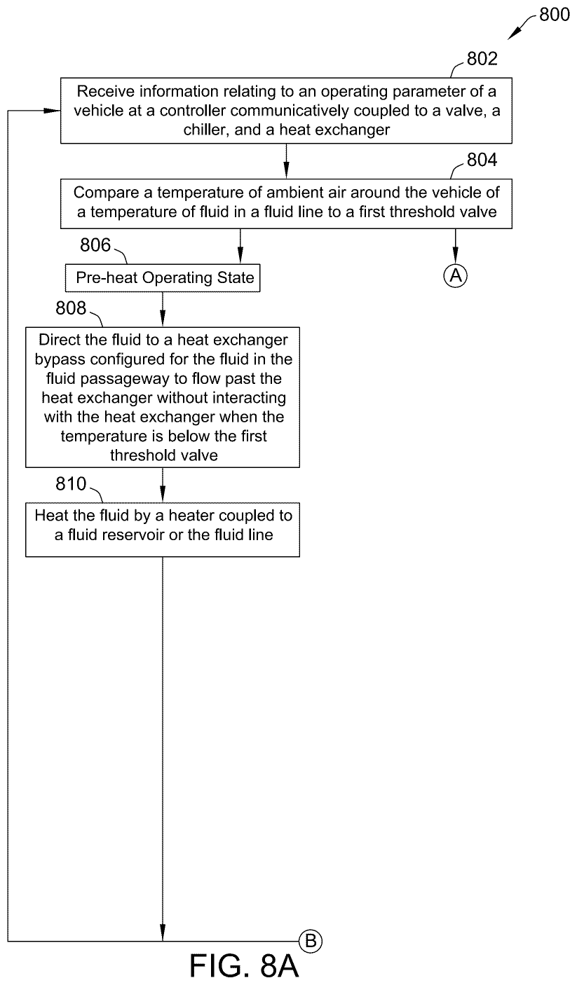

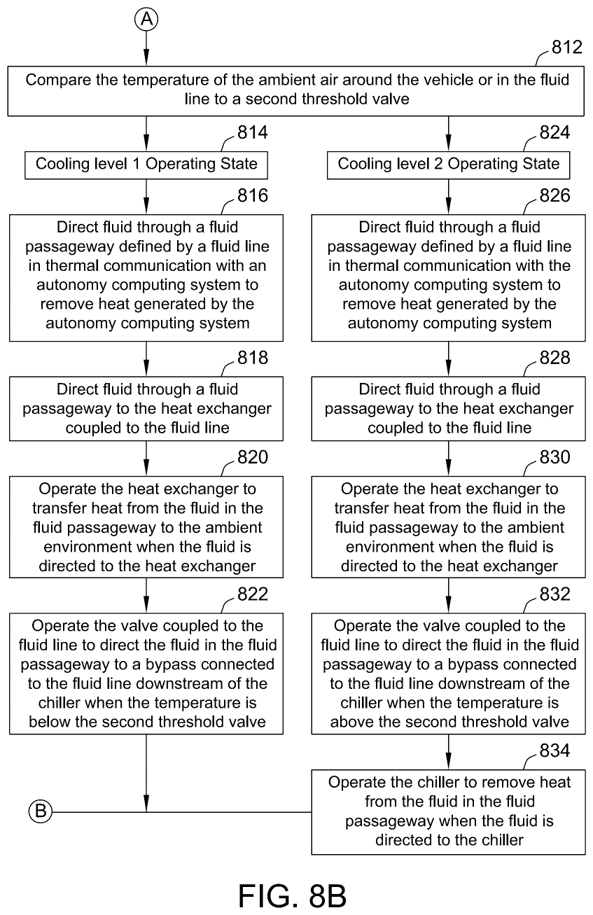

FIGS. 8A and 8B are a flow chart of an example method 800 of cooling vehicle 100 using cooling system 300 (shown in FIG. 3). Referring to FIGS. 3-6 and 8, during operation of cooling system 300, controller 240 receives 802 information relating to an operating parameter of vehicle 100. For example, controller 240 receives information from sensors 202 and/or temperature sensors 316, 318, 320. Controller 240 receives information continually during operation of cooling system 300 and may change operating parameters (e.g., an operating state of cooling system 300) at any time based on the received information. In some embodiments, controller 240 determines an initial operating state of cooling system 300 based on a temperature of ambient environment around vehicle 100 and determines subsequent operating states based on a temperature of fluid in fluid line 302.

In the example embodiment, controller 240 compares 804 a temperature of ambient environment around vehicle 100 or a temperature of fluid in fluid line 302 to a first threshold value. For example, controller 240 receives temperature information from temperature sensor 218, temperature sensor 316, temperature sensor 318, and/or temperature sensor 320 and retrieves the first threshold value from a memory. Controller 240 compares the temperature to the first threshold value and determines an operating state of cooling system 300 based on the comparison. For example, controller 240 may operate cooling system 300 in a pre-heat operating state 806 if the temperature is below the first threshold value. For example, the first threshold value may be below 0° Celsius.

In the pre-heat operating state 806, cooling system 300 directs 808 fluid to preheat line 324 for the fluid in the fluid passageway to flow past heat exchanger 304 without interacting with heat exchanger 304. The fluid is heated 810 by heater 326 coupled to reservoir 328 or fluid line 302 when the fluid is directed through preheat line 324. After heating, the fluid may be directed back to fluid line 302 or to reservoir 328.

Controller 240 compares 812 a temperature of ambient environment around vehicle 100 or a temperature of fluid in fluid line 302 to a second threshold value. In some embodiments, controller 240 may compare a first temperature to both the first threshold value and the second threshold value. For example, if a first temperature is above the first threshold value, controller 240 may compare the same temperature to the second threshold value. In other embodiments, after comparing a first temperature to the first threshold value, controller 240 may receive a second temperature and compare the second temperature to the second threshold value. In the example embodiment, the second threshold value is higher than the first threshold value. For example, the first threshold temperature may be 40° Celsius and the second threshold temperature may be 50° Celsius.

Controller 240 operates cooling system 300 in a cooling level 1 operating state 814 if the temperature is at or above the first threshold value and is below the second threshold value. During cooling level 1 operating state 814, fluid is directed 816 through the fluid passageway defined by fluid line 302 in thermal communication with autonomy computing system 200 to remove heat generated by autonomy computing system 200. The heated fluid is directed 818 through the fluid passageway to heat exchanger 304 coupled to fluid line 302. Controller operates 820 heat exchanger 304 to transfer heat from the fluid in the fluid passageway to the ambient environment when the fluid is directed to heat exchanger 304.

Controller 240 operates valve 314 based on the comparison of the temperatures and the determined operating state. For example, in the cooling level 1 operating state, controller 240 operates 822 valve 314 to direct fluid in the fluid passageway to bypass 312. Accordingly, fluid flows past chiller 306 without interacting with chiller 306 during cooling level 1 operating state.

Controller 240 operates cooling system 300 in a cooling level 2 operating state 824 if the temperature is at or above the second threshold value. When cooling system 300 operates in cooling level 2 operating state 824, fluid is directed 826 through the fluid passageway defined by fluid line 302 in thermal communication with autonomy computing system 200 to remove heat generated by autonomy computing system 200. The heated fluid is directed 828 through the fluid passageway to heat exchanger 304 coupled to fluid line 302. Controller operates 830 heat exchanger 304 to transfer heat from the fluid in the fluid passageway to the ambient environment when the fluid is directed to heat exchanger 304.

In the cooling level 2 operating state, controller 240 operates 832 valve 314 to direct fluid in the fluid passageway to chiller 306. Controller 240 operates 834 chiller 306 to remove heat from the fluid in the fluid passageway when the fluid is directed to chiller 306.

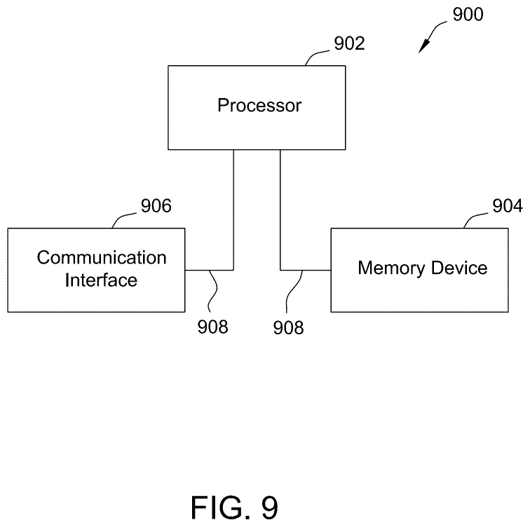

FIG. 9 is a block diagram of an example computing device 900. Computing device 900 includes a processor 902 and a memory device 904. The processor 902 is coupled to the memory device 904 via a system bus 908. The term “processor” refers generally to any programmable system including systems and microcontrollers, reduced instruction set computers (RISC), complex instruction set computers (CISC), application specific integrated circuits (ASIC), programmable logic circuits (PLC), and any other circuit or processor capable of executing the functions described herein. The above examples are example only, and thus are not intended to limit in any way the definition or meaning of the term “processor.”

In the example embodiment, the memory device 904 includes one or more devices that enable information, such as executable instructions or other data (e.g., sensor data), to be stored and retrieved. Moreover, the memory device 904 includes one or more computer readable media, such as, without limitation, dynamic random access memory (DRAM), static random access memory (SRAM), a solid state disk, or a hard disk. In the example embodiment, the memory device 904 stores, without limitation, application source code, application object code, configuration data, additional input events, application states, assertion statements, validation results, or any other type of data. The computing device 900, in the example embodiment, may also include a communication interface 906 that is coupled to the processor 902 via system bus 908. Moreover, the communication interface 906 is communicatively coupled to data acquisition devices.

In the example embodiment, processor 902 may be programmed by encoding an operation using one or more executable instructions and providing the executable instructions in the memory device 904. In the example embodiment, the processor 902 is programmed to select a plurality of measurements that are received from data acquisition devices.

In operation, a computer executes computer-executable instructions embodied in one or more computer-executable components stored on one or more computer-readable media to implement aspects of the disclosure described or illustrated herein. The order of execution or performance of the operations in embodiments of the disclosure illustrated and described herein is not essential, unless otherwise specified. That is, the operations may be performed in any order, unless otherwise specified, and embodiments of the disclosure may include additional or fewer operations than those disclosed herein. For example, it is contemplated that executing or performing a particular operation before, contemporaneously with, or after another operation is within the scope of aspects of the disclosure.

An example technical effect of the methods, systems, and apparatus described herein includes at least one of: (a) increasing capacity of cooling systems to manage heat generated by vehicles; (b) reducing noise and vibration of cooling systems for vehicles; (c) increasing the reliability of vehicles and systems for cooling vehicles; and (d) increasing the cooling efficiency of systems for cooling vehicles.

Some embodiments involve the use of one or more electronic processing or computing devices. As used herein, the terms “processor” and “computer” and related terms, e.g., “processing device,” and “computing device” are not limited to just those integrated circuits referred to in the art as a computer, but broadly refers to a processor, a processing device or system, a general purpose central processing unit (CPU), a graphics processing unit (GPU), a microcontroller, a microcomputer, a programmable logic controller (PLC), a reduced instruction set computer (RISC) processor, a field programmable gate array (FPGA), a digital signal processor (DSP), an application specific integrated circuit (ASIC), and other programmable circuits or processing devices capable of executing the functions described herein, and these terms are used interchangeably herein. These processing devices are generally “configured” to execute functions by programming or being programmed, or by the provisioning of instructions for execution. The above examples are not intended to limit in any way the definition or meaning of the terms processor, processing device, and related terms.

The various aspects illustrated by logical blocks, modules, circuits, processes, algorithms, and algorithm steps described above may be implemented as electronic hardware, software, or combinations of both. Certain disclosed components, blocks, modules, circuits, and steps are described in terms of their functionality, illustrating the interchangeability of their implementation in electronic hardware or software. The implementation of such functionality varies among different applications given varying system architectures and design constraints. Although such implementations may vary from application to application, they do not constitute a departure from the scope of this disclosure.

Aspects of embodiments implemented in software may be implemented in program code, application software, application programming interfaces (APIs), firmware, middleware, microcode, hardware description languages (HDLs), or any combination thereof. A code segment or machine-executable instruction may represent a procedure, a function, a subprogram, a routine, a subroutine, a module, a software package, a class, or any combination of instructions, data structures, or program statements. A code segment may be coupled to, or integrated with, another code segment or an electronic hardware by passing or receiving information, data, arguments, parameters, memory contents, or memory locations. Information, arguments, parameters, data, etc. may be passed, forwarded, or transmitted via any suitable means including memory sharing, message passing, token passing, network transmission, etc.

The actual software code or specialized control hardware used to implement these systems and methods is not limiting of the claimed features or this disclosure. Thus, the operation and behavior of the systems and methods were described without reference to the specific software code being understood that software and control hardware can be designed to implement the systems and methods based on the description herein.

When implemented in software, the disclosed functions may be embodied, or stored, as one or more instructions or code on or in memory. In the embodiments described herein, memory includes non-transitory computer-readable media, which may include, but is not limited to, media such as flash memory, a random access memory (RAM), read-only memory (ROM), erasable programmable read-only memory (EPROM), electrically erasable programmable read-only memory (EEPROM), and non-volatile RAM (NVRAM). As used herein, the term “non-transitory computer-readable media” is intended to be representative of any tangible, computer-readable media, including, without limitation, non-transitory computer storage devices, including, without limitation, volatile and non-volatile media, and removable and non-removable media such as a firmware, physical and virtual storage, CD-ROM, DVD, and any other digital source such as a network, a server, cloud system, or the Internet, as well as yet to be developed digital means, with the sole exception being a transitory propagating signal. The methods described herein may be embodied as executable instructions, e.g., “software” and “firmware,” in a non-transitory computer-readable medium. As used herein, the terms “software” and “firmware” are interchangeable and include any computer program stored in memory for execution by personal computers, workstations, clients, and servers. Such instructions, when executed by a processor, configure the processor to perform at least a portion of the disclosed methods.

As used herein, an element or step recited in the singular and proceeded with the word “a” or “an” should be understood as not excluding plural elements or steps unless such exclusion is explicitly recited. Furthermore, references to “one embodiment” of the disclosure or an “exemplary” or “example” embodiment are not intended to be interpreted as excluding the existence of additional embodiments that also incorporate the recited features. Likewise, limitations associated with “one embodiment” or “an embodiment” should not be interpreted as limiting to all embodiments unless explicitly recited.

Disjunctive language such as the phrase “at least one of X, Y, or Z,” unless specifically stated otherwise, is generally intended, within the context presented, to disclose that an item, term, etc. may be either X, Y, or Z, or any combination thereof (e.g., X, Y, and/or Z). Likewise, conjunctive language such as the phrase “at least one of X, Y, and Z,” unless specifically stated otherwise, is generally intended, within the context presented, to disclose at least one of X, at least one of Y, and at least one of Z.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

What is claimed is:

1. A system for cooling an autonomy computing system of a vehicle, the system comprising:
a fluid line in thermal communication with the autonomy computing system of the vehicle, the fluid line defining a fluid passageway for fluid to receive heat generated by the autonomy computing system;
a heat exchanger coupled to the fluid line and configured to facilitate heat transfer from the fluid in the fluid passageway to an ambient environment when the fluid is directed to the heat exchanger;
a chiller coupled to the fluid line and configured to remove heat from the fluid in the fluid passageway when the fluid is directed to the chiller;
a bypass connected to the fluid line and extending downstream of the chiller;
a valve coupled to the fluid line and to the bypass and configured to selectively direct the fluid in the fluid passageway to the chiller or to the bypass; and
a controller communicatively coupled to the valve, the chiller, and the heat exchanger, wherein the controller is configured to receive information relating to an operating parameter of the vehicle and based on the received information operate the valve to direct the fluid in the fluid passageway to the chiller or to the bypass.

2. The system of claim 1, wherein the operating parameter of the vehicle includes a temperature of the ambient environment around the vehicle or a temperature of the fluid in the fluid passageway, wherein the controller is configured to operate the heat exchanger to remove heat from the fluid in the fluid passageway when the temperature is at or above a first threshold value.

3. The system of claim 2, further comprising a heat exchanger bypass configured for the fluid in the fluid passageway to flow past the heat exchanger without flowing through the heat exchanger, and a heater coupled to the fluid line, wherein the fluid is heated by the heater and directed through the heat exchanger bypass when the temperature is below the first threshold value.

4. The system of claim 2, wherein the controller is configured to operate the valve to direct the fluid to the chiller when the temperature is at or above a second threshold value.

5. The system of claim 4, wherein the controller is configured to operate the chiller to remove heat from the fluid in the fluid passageway when the fluid is directed to the chiller, wherein the chiller is in an Off state when the temperature is below the second threshold value.

6. The system of claim 1, wherein the valve comprises a three-way valve.

7. The system of claim 1, wherein the chiller includes a liquid-to-liquid heat exchanger and a compressor.

8. The system of claim 7, wherein the compressor is connected to an air conditioning system of the vehicle.

9. The system of claim 1, further comprising at least one pump coupled to the fluid line and configured to direct the fluid toward the heat exchanger or the chiller.

10. The system of claim 1, further comprising a first temperature sensor configured to measure an inlet temperature of the fluid upstream of the autonomy computing system, and a second temperature sensor configured to measure an outlet temperature of the fluid downstream of the autonomy computing system.

11. The system of claim 1, wherein the valve and the chiller are coupled to the fluid line downstream of the heat exchanger such that fluid flows from the heat exchanger toward the chiller when the valve is positioned to direct the fluid toward the chiller.

12. A method for cooling an autonomy computing system of a vehicle, the method comprising:
directing fluid through a fluid passageway defined by a fluid line in thermal communication with the autonomy computing system of the vehicle to remove heat generated by the autonomy computing system;
directing fluid through the fluid passageway to a heat exchanger coupled to the fluid line;
operating the heat exchanger to transfer heat from the fluid in the fluid passageway to an ambient environment when the fluid is directed to the heat exchanger;
receiving information relating to an operating parameter of the vehicle at a controller; and
operating a valve coupled to the fluid line to selectively direct the fluid in the fluid passageway to:
a chiller coupled to the fluid line and configured to remove heat from the fluid in the fluid passageway when the fluid is directed to the chiller; or
a bypass connected to the fluid line downstream of the chiller,
wherein the controller is configured to operate the valve based on the received information to direct the fluid in the fluid passageway to the chiller or to the bypass.

13. The method of claim 12, further comprising comparing a temperature of the ambient environment around the vehicle to a first threshold value, wherein the controller is configured to operate the heat exchanger to remove heat from the fluid in the fluid passageway when the temperature is at or above the first threshold value.

14. The method of claim 13, further comprising directing the fluid to a heat exchanger bypass configured for the fluid in the fluid passageway to flow past the heat exchanger without flowing through the heat exchanger when the temperature is below the first threshold value, wherein the fluid is heated by a heater when the fluid is directed through the heat exchanger bypass.

15. The method of claim 13, wherein operating the valve coupled to the fluid line to selectively direct the fluid in the fluid passageway comprises actuating the valve to direct the fluid to the chiller when the temperature is at or above a second threshold value.

16. The method of claim 15, further comprising operating the chiller to remove heat from the fluid in the fluid passageway when the fluid is directed to the chiller.

17. A method of assembling a system for cooling an autonomy computing system of a vehicle, the method comprising:
positioning a fluid line defining a fluid passageway in thermal communication with the autonomy computing system such that fluid in the fluid passageway is configured to receive heat generated by the autonomy computing system;
coupling a heat exchanger to the fluid line to facilitate heat transfer from the fluid in the fluid passageway to an ambient environment when the fluid is directed to the heat exchanger;
coupling a chiller to the fluid line, wherein the chiller is configured to remove heat from the fluid in the fluid passageway when the fluid is directed to the chiller;
connecting a bypass to the fluid line downstream of the chiller;
connecting a valve to the fluid line and to the bypass, wherein the valve is configured to selectively direct the fluid in the fluid passageway to the chiller or to the bypass; and
communicatively coupling a controller to the valve, the chiller, and the heat exchanger, wherein the controller is configured to receive information relating to an operating parameter of the vehicle and based on the received information operate the valve to direct the fluid in the fluid passageway to the chiller or to the bypass.

18. The method of claim 17, further comprising connecting a compressor of the chiller to an air conditioning system of the vehicle.

19. The method of claim 17, further comprising coupling at least one pump to the fluid line to direct the fluid toward the heat exchanger or the chiller.

20. The method of claim 17, further comprising positioning a first temperature sensor to measure an inlet temperature of the fluid upstream of the autonomy computing system, and a second temperature sensor to measure an outlet temperature of the fluid downstream of the autonomy computing system.
